(19) United States
(12) Patent Application Publication
(10) Pub. No.: US 2004/0258984 A1
(43) Pub. Date: Dec. 23, 2004

(54) Integrated thin film batteries on silicon integrated circuits

(75) Inventors: Nava Ariel, Somerville, MA (US); Eugene A. Fitzgerald, Windham, NH (US); Donald R. Sadoway, Waltham, MA (US); Gerbrand Ceder, Wellesley, MA (US)

Correspondence Address: TESTA, HURWITZ & THIBEAULT, LLP, HIGH STREET TOWER, 125 HIGH STREET, BOSTON, MA, 02110, US

(73) Assignee: Massachusetts Institute of Technology, Cambridge, MA

(21) Appl. No.: 10/823,083

(22) Filed: Apr. 13, 2004

Related U.S. Application Data
(60) Provisional application No. 60/462,648, filed on Apr. 14, 2003.

(51) Int. Cl. H01M 6/46; H01M 6/00; H01M 6/12; H01M 6/18; H01M 10/00; H01M 4/58; H01L 31/00

(52) U.S. Cl. 429/152; 429/162; 429/313; 429/231.9; 429/231.95; 29/623.1; 29/623.5

(57) ABSTRACT

A solid-state battery including at least one thin film layer, and method for making same.

### RELATED APPLICATIONS

This application claims the benefit of U.S. Provisional Application 60/462,648 filed Apr. 14, 2003, the entire disclosure of which is hereby incorporated by reference.

### FIELD OF THE INVENTION

This invention relates generally to batteries and particularly to solid-state batteries based on microelectronic technology.

### BACKGROUND

Integrated circuits are designed with the goal of improving performance and reliability while lowering cost. The continuing scaling down of silicon (Si) integrated circuits is targeted to increase operational speeds and to allow more complex functionality. Integration is key to these objectives, and may be considered at several levels: from integrating the circuit components of various functionalities based on transistors to integration of photonics and micro-electro-mechanical system (MEMS) elements on a single Si substrate.

Monolithic integration of devices based on other semiconductors, such as germanium (Ge) and III-V materials, onto Si has been demonstrated with relaxed SiₓGe₁₋ₓ graded buffers as virtual substrates, thereby enabling further advances in the integration process of photonics and electronics. Examples of successfully integrated devices include Ge p-MOSFET, SiGe on insulator (SGOI) for high-speed and low-power applications, optical links between gallium arsenide (GaAs) PIN light-emitting diodes (LEDs) and detector diodes, and AlₓGa₁₋ₓAs/InₓGa₁₋ₓAs LEDs and lasers. With the increasing usage of portable electronic devices such as mobile phones and computers, the next generation of integration will encompass the last missing element of microelectronic circuitry, the powersupply.

Commercially available lithium (Li) rechargeable batteries supply current at voltage values that range between 1.5-4 volts (V) and energy density of 1-120 milliwatt-hour/gram (mWh/g) with thickness on the order of ˜2 millimeters (mm). The low specific energy (<1 mWh/g) and voltage requirements (<2 V) of complementary metal-oxide-semiconductor (CMOS) technology have provided new possibilities for materials and processes, but at present, power sources conventionally remain outside integrated circuit packages.

### SUMMARY

In accordance with the invention, an integrable thin film battery may be fabricated along with, and alongside, the microelectronic components of an integrated circuit. This battery is compatible with Si technology, including materials and processing, and delivers adequate power to energize microelectronic circuitry. Silicon integrated circuit technology has advanced to the point of exceptional thinfilm deposition, patterning and characterization capabilities, enabling battery processing to be brought at least partially into the clean room. The present invention allows the fabrication of the power supply to be part of a back-end process, possibly on the backside of the Si chip, if desired with a charging unit in the form of a MEMS device or a solar cell.

Microelectronic applications require lower voltages (<2 V) than those of many conventional applications, e.g., consumer products. This low potential requirement, combined with advances in thin film technology, allows the utilization of new materials and processes for forming batteries. A thin-film battery, based on conduction of lithium ion or another ion, for example, can be produced in a manner compatible with Si technology in terms of materials, processing, and performance.

The battery of an embodiment of the invention can be very thin, e.g., less than 1 micrometer (μm) or thicker but that comprises of a thin electrolyte e.g. less than 100 nm. A preferred material system for the battery includes a silicon dioxide (SiO₂) electrolyte in combination with a Li-containing electrode layer and a counter electrode. Li-containing electrolytes are well characterized by their extensive use in the battery industry. Similarly, SiO₂ is a material that is widely used in the microelectronics industry. SiO₂ is an electrolyte that doesn't contain lithium. A thin battery combining a Li-containing electrode, a SiO₂ electrolyte and a counter electrode, is formed with microelectronics technology, thereby enabling the integration of batteries and integrated circuits on the same substrate.

In an aspect, the invention features a solid-state battery including a plurality of stacked thin film layers. The solid-state battery is at least partially integrated within the stacked layers and has a thickness less than about 1 μm.

One or more of the following features may be included. The stacked thin film layers may include a cathode layer, an electrolyte layer, and an anode layer. The electrolyte layer may be disposed proximate the cathode layer, the electrolyte layer having a first surface contacting the cathode layer; and the anode layer may be disposed proximate the electrolyte layer, the anode layer contacting a second surface of the electrolyte layer. The electrolyte may include silicon dioxide. The electrolyte may be substantially free of lithium. The electrolyte layer may have a thickness less than about 100 nm.

At least one of the anode and cathode may include silicon and/or lithium. At least one of the anode and the cathode may include at least one of a lithium-metal alloy, a III-V compound, a II-VI compound, a nitride, lithium intercalated into graphite, and an oxide. At least one of the anode and the cathode may include at least one of Li₂₂Sn₅, LiCoO₂, titanium nitride, nickel silicide, cobalt silicide, titanium oxide, and a transition metal oxide. The cathode layer may have a thickness less than about 500 nm. The anode layer may have a thickness less than about 500 nm. The stacked layers may be formed on a substrate, and at least a portion of the substrate may include at least a portion of the solid-state battery. The substrate may include an anode and/or a cathode. The battery may be integrated within and operatively connected to an integrated circuit defined on the substrate. A contact layer may be disposed over the battery.

In another aspect, the invention features a method for forming a solid-state battery, including the steps of forming a plurality of thin film layers over a substrate; and patterning the plurality of thin film layers to define the solid-state battery. The solid-state battery may have a thickness less than approximately 1 μm. The plurality of thin film layers may include a cathode layer, an electrolyte layer, and an anode layer.

One or more of the following features may be included. The electrolyte layer may include silicon dioxide. Forming the electrolyte layer may include dry or wet oxidation. The electrolyte layer may have a thickness less than approximately 500 nm. Forming the layers may include at least one of sputtering and chemical vapor deposition. Patterning the layers may include at least one of photolithography and etching. The solid-state battery may be integrated within and operatively connected to an integrated circuit disposed on the substrate.

In another aspect, the invention features a solid-state battery including a plurality of stacked thin film layers. The solid-state battery is at least partially integrated within the stacked thin film layers, the stacked thin film layers include an electrolyte layer, and the electrolyte layer has a thickness of less than about 100 nm.

One or more of the following features may be included. The stacked thin film layers may further include a cathode layer and an anode layer. The electrolyte layer may be disposed proximate the cathode layer, the electrolyte layer having a first surface contacting the cathode layer; and the anode layer may be disposed proximate the electrolyte layer, the anode layer contacting a second surface of the electrolyte layer.

The electrolyte may include silicon dioxide. The electrolyte may be substantially free of lithium. The electrolyte layer may have a thickness less than about 10 nm. At least one of the anode and cathode may include silicon. At least one of the anode and the cathode may include lithium. At least one of the anode and the cathode may include at least one of a lithium-metal alloy, a III-V compound, a II-VI compound, a nitride, lithium intercalated into graphite, and an oxide.

At least one of the anode and the cathode may include at least one of Li₂₂Sn₅, LiCoO₂, titanium nitride, nickel silicide, cobalt silicide, titanium oxide, and a transition metal oxide. The cathode layer may have a thickness less than about 500 nm. The anode layer may have a thickness less than about 500 nm.

The stacked layers may be formed on a substrate, and at least a portion of the substrate may include at least a portion of the solid-state battery. The substrate may include an anode and/or a cathode. The battery may be integrated within and operatively connected to an integrated circuit defined on the substrate. The battery may include a contact layer.

In another aspect, the invention features a method for forming a solid state battery, including the steps of forming a plurality of thin film layers over a substrate, and chemical mechanical polishing at least one of the thin film layers.

In another aspect, the invention features a method for forming a solid-state battery, including the steps of forming a plurality of thin film layers over a substrate, and patterning the plurality of thin film layers to define the solid-state battery, the solid-state battery including an electrolyte layer having a thickness of less than about 100 nm.

One or more of the following features may be included. The plurality of thin film layers may include a cathode layer and an anode layer. The electrolyte layer may include silicon dioxide. Forming the electrolyte layer may include at least one of dry oxidation and wet oxidation. The electrolyte layer may have a thickness less than approximately 10 nm. Forming the layers may include at least one of sputtering and chemical vapor deposition. Patterning the layers may include at least one of photolithography and etching. The solid-state battery may be integrated within and operatively connected to an integrated circuit disposed on the substrate. At least one of the thin film layer may include polysilicon.

In another aspect, the invention features a solid-state battery including a thin solid electrolyte layer. The electrolyte layer has an initial state and an operative state, wherein the electrolyte layer in the initial state is substantially free of ions and ions conduct through the electrolyte layer in the operative state during operation of the battery.

### BRIEF DESCRIPTION OF DRAWINGS

FIG. 1 is a schematic cross-sectional view of a thin-film multi-cell design with two cells;

FIG. 2 is a schematic view illustrating Li⁺ conductivity in Li-containing electrolytes;

FIG. 3 illustrates Li₂O addition to SiO₂;

FIG. 4 is a schematic view of a LiCoO₂ layered structure;

FIG. 5 is a schematic cross-sectional view of an electro-optical Cu/SiO₂/Si cell;

FIG. 6a-6b are schematic top and side views of a LiCoO₂/SiO₂/polysilicon single cell design;

FIG. 7 is a schematic cross-sectional view of a Li₂₂Sn₅/SiO₂/Si cell;

FIG. 8 is charge plot of a LiCoO₂/SiO₂/polysilicon single cell with 40 nm thick electrolyte; and

FIG. 9 illustrates discharge by shorting the contacts of a LiCoO₂/SiO₂/polysilicon single cell with an electrolyte having a thickness of 40 nm.

### DETAILED DESCRIPTION

1. Battery Characteristics and Design

A distinction may be made between two basic types of cells: the non-rechargeable primary battery which supplies energy during a single discharge and the rechargeable or secondary battery which supplies energy during a plurality of discharges. Two of the major improvements sought by the battery industry are smaller dimensions and high energy densities. Higher energy densities may be achieved by reducing the weight of the battery or by increasing the magnitude of energy exchange in the electrochemical cell or both. The instant application for the power supply will dictate the energy density requirements.

Electric current is produced in a battery when a chemical entity passes from the anode to the cathode doing so by electron transfer reactions at the respective electrode/electrolyte interfaces. The departure of the migratory entity from the anode and entry into the electrolyte is accompanies by the emission of one or more electrons, which accumulate on the anode and give it a negative charge. The departure of the migratory entity from the electrolyte and entry into the cathode is accompanied by the consumption of one or more electrons, which deplete the cathode of same and give it a positive charge. The electrodes are dominantly electronic conductors while the electrolyte is dominantly an ionic conductor. It is precisely this alternation in mode of electrical conduction between anode, electrolyte and cathode that forces said electron transfer reactions to occur, and that consequently results in the generation of electrical current for use in an external circuit. The electrolyte serves also as a physical barrier or spacer that ensures that there be no direct electrical contact between the anode and the cathode.

In commercially available batteries, the electrolyte is usually an aqueous solution, either acidic or alkaline containing dissolved ions of the migratory entity or an organic solvent containing appropriate ions. Among the merits of a liquid electrolyte are its good contact with the electrodes, high ionic conductivity and high electronic resistance (negligible electronic conductivity). Batteries containing liquidelectrolyte suffer from corrosion of the electrodes (so-called self discharge) and, in the case of aqueous electrolytes, consumption of the water acting as solvent due to electrolysis that occurs during recharge (in secondary batteries). Safety and environmental concerns are met by the robust packaging that protects batteries containing liquid electrolytes. The battery packaging adds to the weight of the battery at the expense of overall energy density.

A solid-state electrolyte is an electronically insulating solid-phase material with high ionic conductivity, i.e., a low electronic transfer number tₑ as defined in equation 1, where σₑ and σᵢ are the electronic and ionic conductivities, respectively.

$${t}_{e} = \frac{{σ}_{e}}{{σ}_{i} + {σ}_{e}} \qquad ( 1 )$$

A solid-state electrolyte may have a plurality of charge carriers, both cationic (positive) and anionic (negative) or in the extreme only a single charge carrier. In the latter case the electrolyte is termed a single-ion-conductive. A solid electrolyte should wet the surface of the electrodes to establish good electrical contact with them, and should also be chemically and electrochemically stable in the presence of the electrode materials. In principle, much higher energy densities are attainable in an all-solid-state battery.

The anode, on discharge, is the electron source, i.e., the site of oxidation, injecting ions into the electrolyte and electrons into the external circuit. The anode should be electronically conductive and should produce ions that will diffuse rapidly through the electrolyte. A good anode, therefore, should be made of a highly electropositive light metal or light metal-containing alloy or compound with a very high electronic conductivity.

The cathode, on discharge, is the electron sink, i.e. the site of reduction, retrieving ions from the electrolyte and electrons from the external circuit. One way of storing the ions may be by intercalation in the cathode material. The cathode active material should be a mixed conductor of ions and electrons to enable fast and effective electron and ion exchange. A good cathode, therefore, may be made of a material with high electronic conductivity as well as high diffusivity of the migratory ionic species. One such type of material intercalates the migratory ion, the insertion of whih triggers a reduction in valence of one of the cathode constituents.

The electrodes are connected to the external circuit via contacts termed current collectors, which are electrically conductive materials, typically metals, that do not react with, or allow diffusion of the migratory ions, e. g., lithium.

The change in the Gibbs free energy (ΔG) for a battery discharge is given by equation 2:

ΔG=nFV_{oc} (2)

where

n=the number of electrons exchanged in the electron transfer reactions at the electrodes,

F=the Faraday constant=96487 C/mol (1 mole of charge), and

V_{oc}=the open circuit voltage (OCV) or the electromotive force, which is given by the potential difference between the two electrodes.

The theoretical value of energy (Eₜₕ) achievable from an electrochemical cell is given by equation 3:

Eₜₕ=xnFV_{oc} (3)

where

x=the number of moles taking part in the reaction.

2. The Integrated Thin Film Power Source

2.1 Integration

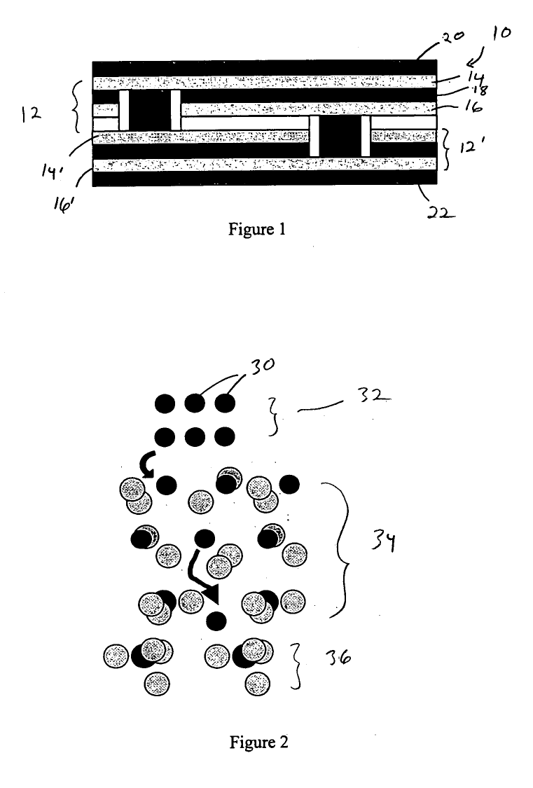

Referring to FIG. 1, a multi-cell design of the invention involves a thin-film solid-state battery 10 having a low operational voltage with low resistance and sufficiently high capacity. Here, single cells 12 and 12′ are connected. First single cell 12 has a first thin-film anode 14 separated from a first thin-film cathode 16 by a thin-film electrolyte 18, and second single cell 12′ has a first thin-film anode 14′ separated from a first thin-film cathode 16′ by a thin-film electrolyte 18′. First single cell 12 is connected to second single cell 12′ in parallel, i.e., first anode 14 is connected to second anode 14′ and first cathode 16 is connected to second cathode 16′. Battery 10 also has a front contact 20 and a back contact 22. The technology to produce a structure such as battery 10 having thin layers on the order of several nanometers (nm) that are planar, uniform, and precise, may employ processing techniques used in a Si chip manufacturing and can be grown as part of the back-end process, possibly on the back side of the Si chip, as discussed in greater detail below.

2.2 SiO₂ as a Solid Electrolyte

One of the most familiar, fundamental, and widespread materials in silicon integrated circuit technology is silicon dioxide (SiO₂). SiO₂ performs numerous functions in circuits, including providing insulation between interconnects or devices, and forming a gate dielectric under a gate electrode. SiO₂ may be grown in various ways to provide film of various quality and thickness. SiO₂ is an insulating material, with resistivity>10²⁰ Ω-cm. SiO₂ is known to be a fast ion conductor for ions such as Cu²⁺, Na⁺, Li⁺, etc. Thus, it is to be expected that SiO₂ be suitable for use as a solid-state electrolyte if the SiO₂ layer is thin and highly uniform. Such a layer could therefore function as an electrolyte in a solid-state battery integrable with silicon technology. Owing to the integration with Si integrated circuits and the use of Si microprocessing technology, it is possible to create thin layers of SiO₂ in conjunction with similarly thin device layers. The SiO₂ electrolyte is unconventional because most solid-state electrolytes are thick and therefore need to be lithiated to have good conductivity and to support electron transfer reactions at the electrodes. SiO₂ is an electrolyte which does not contain lithium or doped with a lithium containing salt. For example, referring to FIG. 2, in a conventional battery, lithium atoms 30 from an anode 32 that typically contains elemental lithium enter a thick conventional lithium-containing electrolyte 34 and lithium ions from the electrolyte 34 move toward a cathode 36.

One might expect that an electrolyte not containing lithium ions would become positively charged when lithium ions diffuse through it, thereby creating an electric field that would halt the diffusion. This may be true for common solid electrolytes having thicknesses of at least 1-2 μm. However, it is found that it is possible to utilize SiO₂ as an electrolyte in conjunction with a lithium-containing anode when the SiO₂ electrolyte is sufficiently thin to allow rapid diffusion of lithium ions through it. In the batteries of the invention, the thickness of the electrolytes defined by SiO₂ films is preferably in the range of approximately 5-999 nm, desirably 5-100 nm, and ideally <10 nm.

Sodium ion is a fast diffusant in SiO₂, with a diffusivity D₀ of 6.9 cm²/sec, and an activation energy Eₐ of 1.3 eV. The fast diffusivity of sodium has presented a problem in fabricating CMOS devices generally (shifts of the threshold voltage of metal oxide silicon field effect transistors [MOSFET] and therefore major relaiability problem), and as a result the industry frequently utilizes hydrochloric acid (HCl) and hydrogen peroxide (H₂O₂) mixture dips as a part of a pre-oxidation cleaning procedure to negate the presence of Na and other alkaline metal ions on the silicon wafers. Lithium is a smaller and faster ion than sodium, and therefore lithium ions diffuse quickly through SiO₂.

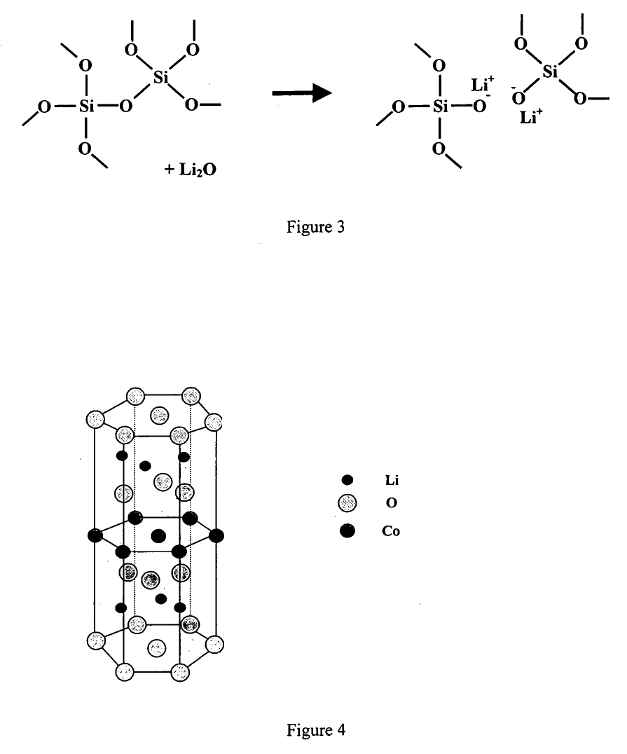

The addition of sodium oxide to silica as a structural modifier causes the silica structure to change, but local charge neutrality is maintained. The addition of Li₂O to SiO₂ may aid Li⁺ transport and allow for thicker SiO₂ films, but the trade-off is that this material may be less compatible with clean room processing. Referring to FIG. 3, the addition of Li₂O to SiO₂ may modify the SiO₂ structure. Bridging oxygen atoms (bonded to two Si atoms) transform into non-bridging atoms and the cations are localized in their vicinity, providing local neutrality. As a result, the material becomes more ionic and therefore is more supportive of ionic transport.

2.3 Silicon as an Electrode

When reacted with lithium, silicon forms four compounds, i.e., Li₁₂Si₇, Li₇Si₃, Li₁₃Si₁₄, and Li₂₂Si₅, in order of increasing Li content. The favorable potential of silicon and Si—Li alloys as electrodes, with a theoretical capacity density of up to 1967 mAh/g, has inspired many researchers to study its electrochemical behavior at various temperatures as well as the properties of different Si—Li compounds. Li—Si alloys are capable of reversible specific capacity higher than 1700 mAh/g. Naturally, Si electrodes are highly advantageous from a process perspective, since their formation can be readily integrated into conventional microdevice fabrication processes.

A relatively smooth, clean, continuous interface between a Si electrode and an electrolyte may be achieved in a SiO₂-containing cell with a doped silicon anode (to make the silicon electronically conductive). In conventional solid-state batteries, the electrode/electrolyte interface is a source of problems, sometimes leading to failure because of instabilities such as chemical reactions and the roughness of the interface, which impose minimum thickness limitations on the electrolyte that are needed to prevent from the cell from shorting. SiO₂, by contrast, may be grown thermally on the substrate or on polycrystalline silicon layers in a clean environment, thus providing the high quality of the well-known SiO₂/Si interface that has not been exposed to an atmospheric ambient.

Unfortunately, a large volume change tends to accompany Li insertion into an electrode formed from silicon or some metals because of the larger lattice constant of, e.g., Li—Si compounds in comparison to, e.g., Si. The volume change accommodation during charge of the silicon depends on the current densities used. High current densities do not allow the inserted lithium ions to spread uniformly in the silicon. Accordingly, one approach for minimizing the adverse effects of volume changes is to use lower rates of charging and discharging, thereby providing more time for the Li atoms to diffuse and preventing local accumulation. Another approach is to utilize a thin (˜300 nm) layer of polysilicon as an electrode deposited on an insulating layer. Such a layer has a larger surface-to-volume ratio than bulk Si. Moreover, the presence of grain boundaries in the polysilicon layer may promote faster uptake of lithium than is possible in single crystal Si. The limited thickness of the Si electrode layer is desirable for reversible use of the cell although in some batteries, a thicker (than 300 nm) polysilicon anode is utilized. The polysilicon is doped to make it electronically conductive and a thin undoped polysilicon layer may be dposited on top of it to improve the quality of SiO₂ that is grown.

2.4 Lithium Source

Pure elemental lithium melts at 180.7° C., a relatively low temperature for back-end processing. For example, metallization to form contacts to the cell itself requires an anneal at 300°-400° C. Lithium metal is highly reactive and generally requires working in an inert environment, such as argon or helium. Table 4 presents some of the relevant formation free energy values of compounds that may be formed from Li, Si and O.

TABLE 4
Gibbs free energy values for formation of relevant
Li—Si—O compounds

| | Standard Gibbs Free Energy of Formation |
|---|---|
| | at 298 K |
| Compound | [kJ/mole] |
| Li₂O | −610.027 |
| Li₂O₂ | −649.462 |
| SiO₂ | −923.219 |
| Li₂SiO₃ | −1673.439 |
| Li₄SiO₄ | −2366.246 |
| Li₂Si₂O₅ | −2598.325 |

The Gibbs free energy is a measure of the chemical stability of a compound. If the value of the standard Gibbs free energy of formation of a compound (Δ_{f}G°) is negative, then it is stable and will form if the necessary reactants are present. The standard Gibbs free energy values reported in Table 4 indicate that elemental Li placed on SiO₂ is not likely to be chemically stable, even at room temperature, and will probably reduce SiO₂ to form Li₂O and elemental silicon. This reaction, given in Equation 4, has a Δ_{f}G°=2×(−610.027)+923.219=(−296.8) kJ for 1 mole of O₂:

4Li+SiO₂→2Li₂O+Si (4)

The fact that the change in Gibbs free energy associated with the reduction of SiO₂ by lithium to form Li₂O and silicon is negative, indicates that Reaction 4 would probably occur spontaneously when elemental lithium is deposited on SiO₂. Other compounds with negative values of free energy may also form. With these considerations in mind, at least two types of alternative lithium sources are useful in connection with a SiO₂ electrolyte, namely, a lithium metal alloy, e.g., tin, and/or a lithiated transition metal oxide, such as LiCoO₂.

Lithium and tin form seven different compounds, from Li₂Sn₅ having 28.6% at lithium, to Li₂₂Sn₅ having 81% at lithium. Li₂₂Sn₅ (or Li_{4.4}Sn) has a high theoretical capacity density (˜994 mA/g), is thermally stable (melts at 765° C.) despite its high lithium content, and is chemically stable with SiO₂. The volume change of the Sn—Li electrode upon charge and discharge of the cell, however, may have to be addressed in some embodiments as discussed above.

Lithiated oxides have been used as anodes in a thick-film solid-state “rocking chair” battery in which the ions are transferred back and forth between two intercalation compounds. For example, LiCoO₂ has been used as the lithium source in a SiTON/LiPON/LiCoO₂ battery. Referring to FIG. 4, LiCoO₂ has a layered hexagonal structure in which the oxygen anions form a closed packed network with the lithium and cobalt cations on alternating (111) planes of the cubic rock salt sub-lattice.

Assuming full intercalation (i.e., one lithium ion per CoO₂ unit cell), the capacity density of LiCoO₂ is approximately 290 mAh/g. With LiCoO₂, however, this assumption is usually inaccurate and a more practical assumption is a reversible cycle involving half of the Li ions, which gives a theoretical capacity of ˜145 mAh/g. To increase absolute capacity, a multi-cell may be produced (see, e.g., FIG. 1). Upon lithium extraction from the LiCoO₂, the oxidation state of Co is changed from Co⁺⁴ to Co⁺³ and, in contrast to spinel structured materials, the volume change associated with that process is small and possibly even negative. The lattice slightly expands with lithium de-intercalation, which might present a problem beyond 0.5 Li de-intercalation, i.e., structural instability may occur due to a change in volume.

2.5 Current Collectors

Current collectors or contacts are electrically conductive materials, e.g., metals, that do not react with or allow diffusion of ions. Preferred metals for use with lithium sources include copper (Cu), titanium (Ti), and aluminum (Al), and combinations thereof. The metallization interconnects in microelectronics are currently moving from the use of Al and SiO₂ as the metal and inter-metal dielectric, respectively, to Cu and low-k dielectrics in order to reduce capacitance delays. From the perspective of thin-film battery fabrication using lithium sources, this is a positive trend because Al reacts with Li to form Li—Al alloys, whereas Cu is more inert to lithium. Nevertheless, metals used for silicides, such as Ti, may be used to deposit a lithium diffusion barrier as an integral part of the contact and prevent direct Li and Al interaction. More generally, metal layers that are inert with respect to the material comprising an electrode, i.e., a cathode or anode, may be formed between the electrode and a highly conductive metal to improve contact.

2.6 Other Materials

Li₂₂Sn₅ or LiCoO₂/SiO₂/Si cells are only a few of the many materials that may be employed as sources in the thin-film batteries of the invention. Some other useful anode materials are titanium nitride (TiN), a material commonly used in chip fabrication, and various silicides such as nickel silicide, cobalt silicide, chromium silicide, or titanium silicide that are Si-compatible as well. Other potential anode materials are, for example, Li-M alloys in which M is a metal, e.g., Al, tin (Sn), zinc (Zn), lead (Pb), and cadmium (Cd). Other possible materials include III-V compounds such as aluminum antimonide (AlSb), indium antimonide (InSb), gallium arsenide (GaAs), and indium phosphide (InP); II-VI compounds such as cadmium telluride (CdTe) and cadmium selenide (CdSe); nitrides such as tantalum nitride (TaN), Sn₃N₄, Zn₃N₂, TiN, and silicon tin oxynitride (SiSnON); lithium intercalated into graphite (LiC₆); and oxides, including transition metal oxides such as LiCoO₂, LiMn₂O₄, lithiated molybdenum oxide (MoO₃), lithiated vanadium oxide (V₂O₅), lithiated V₃O₈, TiO₂, Ti₂O₄, LiNiO₂, LiNiₓCo₁₋ₓO₂, etc., as well as other oxides such as tungsten oxide (WO₃). An oxide may be either a cathode or an anode, depending on the difference in potential between it and the opposite electrode. A battery may be made from, for example, two transition metal oxides, with one containing Li and the other being substantially free of Li, i.e., a “rocking chair” battery. The transition metal oxide that has a potential closer to that of lithium, the conventional reference in lithium-containing batteries, is the anode. Another way to think about the issue is to consider the chemical potential of lithium in the two electrodes comprising the battery. The electrode possessing the higher chemical potential of lithium is the anode.

TiO₂, a silicon-compatible material, may serve as a cathode, for example. Further, all of the oxides suggested above for anodes may also be used as cathodes. Transition metal oxides may be preferable for use as cathodes because the chemical potential of lithium in these materials is very low which translates into a large potential difference with lithium. On the other hand, a transition metal oxide may serve as an anode when it is lithiated. Additional materials that may be used as cathodes are sulfides, e.g., titanium sulfide (TiS₂) and MoS₃. Any other layered or spinel-structured material that can conduct electronically and enable lithium intercalation in it may also serve as a cathode.

The electrolyte may be formed from SiO₂. Further, the electrolyte may include SiO₂ to which Li has been added, lithium phosphorous oxynitride (LiPON), or lithium iodide (LiI).

2.7 Cu Cells for Electro-optic Applications

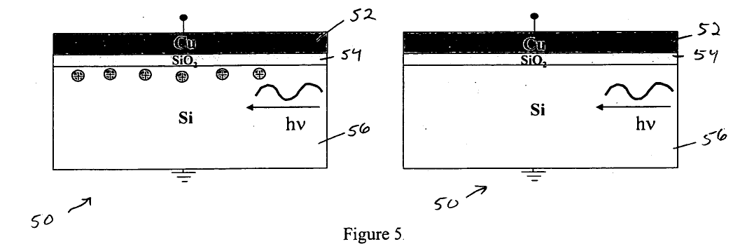

The fast diffusion of Cu⁺ in SiO₂ is greatly enhanced under bias and temperature conditions (D˜2.5×10⁻⁸e^{-0.93eV/{KT}} cm²/sec, with a mobility μ at room temperature of approximately 2.8×10⁻²² cm²/V sec). From the CMOS perspective, this is detrimental and much research is being conducted on various diffusion barriers for Cu in SiO₂ and other dielectric materials. Referring to FIGS. 5a-5b, on the other hand, this diffusion property may be turned to advantage in processes other than CMOS, where ion diffusion produces a desired effect. As shown in the figure, a thin-film electro-optical Cu/SiO₂/Si device 50 may be produced, having a Cu terminal 52, a SiO₂ electrolyte 54 and a Si terminal 56. Ions 58 may be introduced into the electrolyte 54 (FIG. 5a), or ions 58 may be removed from the electrolyte 54 (FIG. 5b). The presence of ions 58 in the electrolyte 54 may change the optical properties of silicon, e.g., the refractive index, and thus create an electro-optical device. Although the energy formation values for Cu₃Si and Cu₅Si may be too low (−13.6±0.3 kJ/mole and −10.5±0.6 kJ/mole respectively) for some battery applications, a Cu cell may have applications in other fields, such as an electro-optical switch, in which the refractive index of the Si is altered by the diffusion of Cu into the Si. Thus, in contrast to conventional electro-optical materials that use carriers like electrons and holes, Si terminal 56 of the thin film electro-optical device 50 may have a large index change because of the use of ions instead of traditional carriers.

A copper-based device may also be realized using a cathode material that forms compounds with Cu having more negative energies of formation (e.g., CuFeO₂ or CuFeS₂) than those of Cu—Si. Although the potential difference between Cu and its silicides is small, a battery based on Cu may not have good efficiency owing to kinetic limitations associated with the movement of copper and its ions. Such a device, however, may have other applications, such as an optical switch or an attenuator.

3. Processing

The integrated battery of the invention may be created in a clean-room environment used typically for Si-based chip fabrication. The process is compatible with existing integrated circuits fabrication technology.

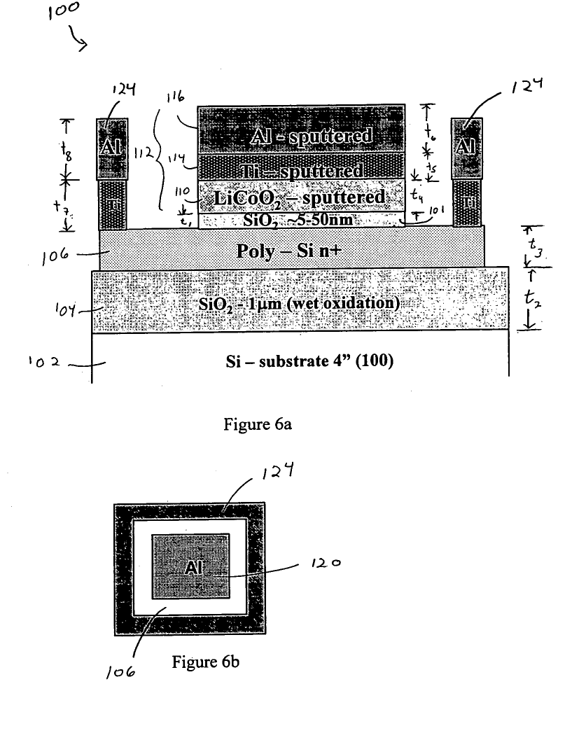

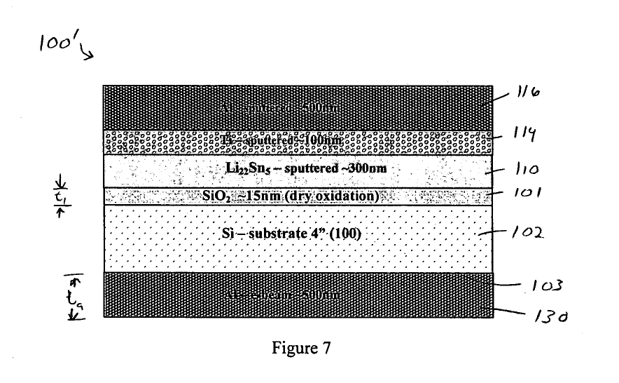

FIGS. 6a, 6b, and 7 collectively illustrate two single cell design embodiments. A battery cell 100, 100′ includes an electrolyte layer 101 formed over a substrate 102. Substrate 102 may be, for example, a silicon wafer. Electrolyte layer 101 may contain SiO₂ that may be thermally grown, e.g., by dry or wet oxidation to provide a uniform, clean film, with a thickness t₁ of, e.g., 15 nm. SiO₂ may also be sputtered or grown by chemical vapor deposition (CVD) or by thermal evaporation.

In some embodiments, prior to the formation of electrolyte layer 101, an insulating dielectric layer 104 may be formed over substrate 102. Dielectric layer 104 may be formed by, e.g., wet oxidation and may have a thickness t₂ sufficient so that dielectric layer 104 acts as an electronic and ionic insulator, e.g., t₂=1 μm. Wet oxidation may be used to form dielectric layer 104 because it is faster than dry oxidation, and high film purity is not critical for dielectric layer 104. The insulating layer can be Si₃N₄ as well (grown by CVD or sputtering) or any other insulating and Li impermeable layer. Its thickness may vary as long as its electronically insulating and impermeable to lithium ions.

An anode layer 106 may be formed over dielectric layer 104, also prior to dielectric layer 104 formation. Anode layer 106 may include polycrystalline silicon (“polysilicon”) that is formed by, e.g., low pressure chemical vapor deposition (LPCVD) with a precursor such as silane (SiH₄) at, e.g., 650° C. or 550° C. and may be made conductive by ion implantation (e.g., implanting As or P for n-type polysilicon or B for p-type silicon) at a low implantation energy, e.g., <200 keV). Alternatively, polysilicon may be made conductive by in situ doping using a precursor such as arsine (AsH₃) or phosphine (PH₃) for n-type or diborine (B₂H₆) for p-type during growth. Dopant concentration may be approximately 10²⁰/cm³. An anneal may be performed at, e.g., 950° C. for 30 minutes after ion implantation or for 12 minutes after in situ doping growth to activate the dopants. This anneal may also serve to relieve damage of the crystalline structure of the silicon caused by implantation. Anode layer 106 may have a thickness t₃ of, e.g., 300 nm or thicker (depending on cathode thickness). Criteria for selecting thickness t₃ are given below. To improve interface smoothness, a chemical mechanical polishing (CMP) step may be added. The doped polisilicon is polished for typically less than a minute using a e.g., NaOH slurry and its roughness is reduced significantly before deposition of the e.g., 15 nm undoped polysilicon layer or before the oxidation step. In case a CMP step is included, a chemical cleaning step is added, using e.g., a mixture of H₂SO₄:H₂O₂ 3:1 (“pirhana clean”) after polishing.

Then, electrolyte layer 101 may be formed over polysilicon layer 106 by, e.g., dry oxidation at 950° C. for 12 minutes. In order to prevent the dopants from segregating into the electrolyte layer 101 during oxidation, an additional layer of undoped poly, typically 15 nm thick, may be deposited on the doped polysilicon layer 106 and oxidized by dry or wet oxidation at e.g. 700° C. (low temperature inhibits dopants diffusion from doped polysilicon layer). The electrolyte layer 101 may have a thickness of, e.g., 10 nm.

A cathode layer 110 is formed over silicon dioxide layer 101. Cathode layer 110 may include, for example, LiCoO₂ that is rf-sputtered from a LiCoO₂ target, or Li₂₂Sn₅ that is rf sputtered from a Li₂₂Sn₅ target, and may have a thickness t₄ of, e.g., 250 nm or thicker (depending on anode thickness). Thickness t₄ may be estimated from a ratio between t_{LiCoO2} (thickness of LiCoO₂) and t_{Si} (thickness of polysilicon). This ratio may be calculated by considering a ratio of Li and Si atoms that form the first Si—Li compound to be formed:

$$\begin{matrix}\frac{{t}_{{LiCoO}_{2}} \times {ρ}_{{LiCoO}_{2}} \times 0.5 \times {A}_{{LiCoO}_{2}}}{{M}_{{LiCoO}_{2}}} ⇒ £ of Li atoms & ( 5 ) \\ \frac{{t}_{Si} \times {ρ}_{Si} \times {A}_{Si}}{{M}_{Si}} ⇒ £ of Si atoms & ( 6 )\end{matrix}$$

For example, to form Li₂₁Si₁₂, a ratio of 1.7 Li atoms to 1 Si atom results in a thickness ratio of t_{LiCoO2}/tₛᵢ of ˜17 for the entire polysilicon layer to react. To alleviate the expected volume changes and to keep the cathode thickness in the nanometer range, a thickness ratio of ˜1 can be used. A total thickness t₁₀ representing the sum of the thickness of anode layer 106, electrolyte layer 101, and cathode layer 110 may be less than, for example, 1 μm. The total thickness t₁₀ may be also thicker than e.g., 1 μm but the electrolyte layer 101 may be thinner than e.g., 100,nm (the anode layer 106 and cathode layer 110 may be thicker than e.g., 500,nm, but the electrolyte layer 101 is thinner than e.g., 100 nm).

In a completed battery cell, such as cell 100, in a discharged state Li atoms are disposed in the cathode, e.g., cathode layer 110. Cell 100 is fabricated in a discharged state. Anode layer 106 has a lower potential difference with respect to Li, e.g., Si has a potential difference of ˜1 V with respect to Li. Cathode layer 110 has a higher potential difference with respect to Li, e.g., LiCoO₂ has a potential difference of ˜4 V with respect to Li. During the charging of cell 100, Li atoms move from cathode layer 110 to anode layer 106 through electrolyte 101. In an embodiment in which cathode layer 110 is formed from LiCoO₂, the structure of cathode layer 110 may become unstable if, e.g., more than one-half of the Li atoms exit the cathode layer 110. In some materials, however, all of the Li atoms may be extracted without becoming unstable. When Li ions enter anode 106, they react with the silicon in anode 106, thereby changing the potential of anode 106. If anode 106 is too thick, e.g., comprises an entire substrate, the Li ions diffuse away from an interface between anode 106 and electrolyte 101 and the potential at the interface does not change.

Metallization layers may be formed to enable external contact to cathode layer 110. For example, a cathode contact 112, or a current collector, may be formed over cathode layer 110. The cathode contact 112 may include a barrier layer 114. Barrier layer 114 may include a material that is not reactive with the Li in the underlying cathode layer, such as Ti deposited by, e.g., DC sputtering, and having a thickness t₅ of, e.g., 100 nm. A contact metal layer 116 may be formed over barrier layer 114. Contact metal layer may include, for example, Al deposited by, e.g., DC sputtering, and having a thickness t₆ of, e.g., 500 nm.

After deposition, cathode contact 112, cathode layer 110, and electrolyte layer 101 are patterned by, e.g., photolithography and wet etch to expose a portion of anode layer 106 and to define, in conjunction with anode layer 106, a battery cell 120. A suitable wet etch for selectively removing portions of cathode contact 112 may be, for example, exposure to a solution of 20:1:1 of H₂O:H₂O₂:HF at room temperature to etch Ti. To remove Al, a suitable etchant is, for example, “Aluminum etchant—type A” (H₃PO₄:HNO₃:HAc:H₂O at a ratio of 16:1:1:2) at 50° C. Cathode layer 110 may be removed by, for example a wet etch such as HCl at 50° C. if not removed already by Ti etch.

Anode contacts 124 may be formed to contact anode layer 106. Cathode contact 112 is covered with photoresist. Anode contacts 124 are defined by, e.g. forming a barrier layer 126 by, e.g., depositing Ti by electron-beam evaporation and forming a metal layer 128 by, e.g., depositing Al by electron-beam evaporation. Portions of barrier layer 126 and metal layer 128 formed over the photoresist are lifted off in acetone with the photoresist (known as a “lift-off” process in silicon integrated circuits fabrication). Barrier layer 126 may have a thickness t₇ of, e.g., 100 nm, and metal layer 128 may have a thickness t₈ of, e.g., 500 nm. Front contact definition may include photolithography accompanied by wet-chemical etching for patterning. An anneal at, e.g., 400° C. for 30 minutes in, e.g., N₂, may be performed to improve contact and cathode quality.

Referring to FIG. 7, a single discharge cell 100′ with cathode 110 containing Li₂₂Sn₅ is illustrated with silicon substrate 102 as a counter-electrode, rather than a thinner, deposited, layer of polysilicon as described above with reference to FIGS. 6a-6b. Also, a back contact layer 130 is formed on a backside of substrate 102 by, e.g., e-beam evaporation. Back contact layer 130 may be formed by a combination of photoresist definition, e-beam evaporation of a metal such as Ti to a thickness of about 100 nm and Al to a thickness of about 500 nm over the entire backside 103 of substrate 102, and lift-off to selectively remove the metal from the backside 103. Back contact layer 130 may include Al and may have a thickness t₉ of, e.g., 500 nm. An anneal at, e.g., 400° C. for 30 minutes in, e.g., nitrogen, may be performed to improve contact quality. This structure may be used in conjunction with Li₂₂Sn₅ anode material. In a working cell, the structure 100 illustrated in FIGS. 6a and 6b is preferred, i.e., a battery cell 100 having thin anode layer 106 with a defined thickness of, e.g., polysilicon is preferable to an anode comprising a single-crystal Si substrate 102.

Although single-level batteries are illustrated in FIGS. 6a-7, a multi-layered cell (see, e.g., FIG. 1) may be fabricated by planarizing films, e.g., cathode and/or anode layers 110, 106, between cell depositions. Planarization may be performed by, e.g., chemical mechanical polishing (CMP).

This experimental battery demonstrates the utility of SiO₂ as an ultra-thin electrolyte in battery technology. It also shows that a particular maximum charging/discharge rate may exist because high currents may cause the precipitation of higher ion content alloys prematurely, leading to failure.

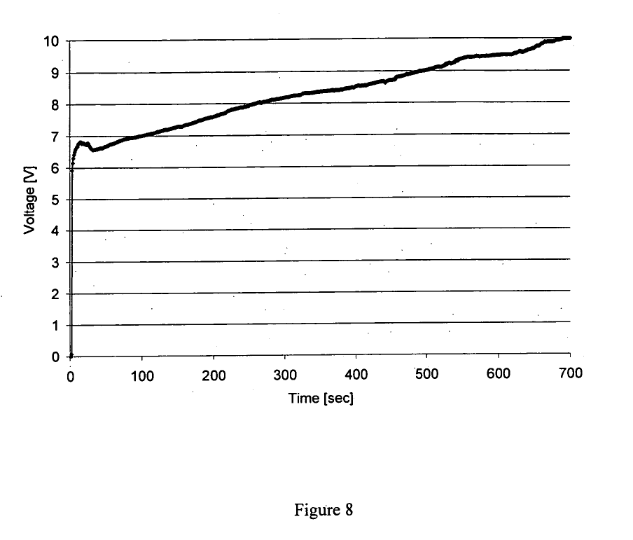

Referring to FIG. 8, a charge plot is given for a LiCoO₂/SiO₂/polysilicon cell with oxide thickness of 40 nm and active area [cathode area] of 0.5×0.5 mm². Voltage increases with time, although it is higher than expected due to high series resistance that can be lowered by reducing oxide thickness.

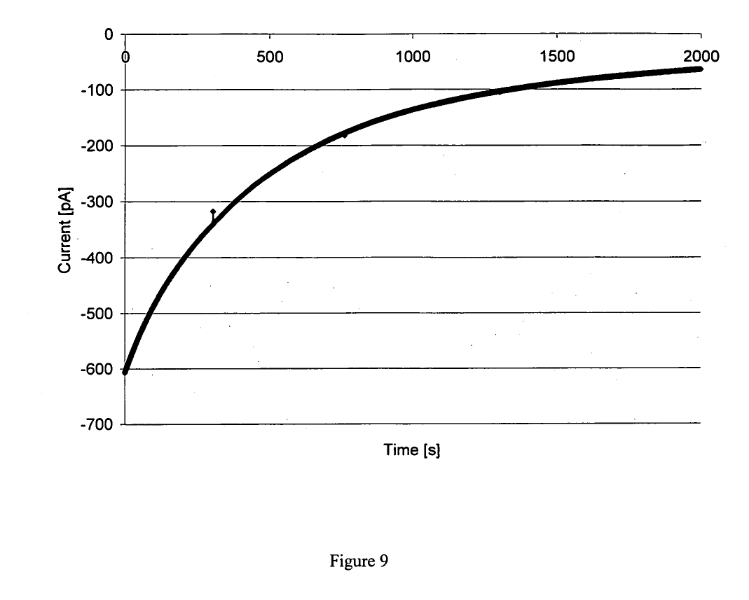

Referring to FIG. 9, a discharge plot is given for a LiCoO₂/SiO₂/polysilicon cell with an oxide thickness of 40 nm and an active area [cathode area] of 0.5×0.5 mm² that was charged for 1000 sec at 1C rate (current density corresponding to an hour long charge) by shorting the cell (setting V between the contacts to be zero) and measuring the current. The negative current is an indication for current coming out of the cell into the parameter analyzer showing that the cell can give power.

3.1 LiCoO₂ Cathode Deposition and Optimization

In a preferred embodiment, in deposition of LiCoO₂, the substrate temperature is increased to ˜200° C. during deposition and the sputtering gun power is reduced to 200 W, thereby greatly improving the film quality. In some embodiments, one may use pulsed laser deposition (PLD), i.e., deposition using a laser heating a target, to grow LiCoO₂ at deposition temperatures of 100-300° C., wherein the quality of the film as well as the level of its crystallinity increases with deposition temperature. Alternatively, one may use a post deposition thermal treatment at 600-700° C. to increase the level of crystallinity in sputtered LiCoO₂ and to improve the diffusion coefficient of lithium in the film.

All of the foregoing steps are readily integrated into a silicon integrated circuit process flow. They are either typical processes already performed for integrated circuit fabrication, or they may be performed by relatively minor modification of existing steps. For example, lithium is not typically used in integrated circuit fabrication, but the lithium layers of the invention may be deposited by, e.g., changing a target in an existing sputtering tool. Some of the processing methodes of silicon integrated circuit fabrications are new to battery processing and can benefit the field by being implemented in fabricating the battery. For example, implementation of CMP as planarization methos is important to create smooth interfaces allowing for thinner layers (e.g. a thin electrolyte). An integrated battery may be deposited, therefore, with Si-chip compatible technology. SiO₂, when thin, can act as an excellent solid-state electrolyte. A thin film cathode may include LiCoO₂, and a thin film anode may include polysilicon. The cathode and anode layers may be thicker while separated by a thin electrolyte. Many alternative anode and cathode materials, however, may be used. In addition, modification of the SiO₂ electrolyte, such as by the addition of Li₂O, to increase ion transport may also improve call performance.

3.2 Solar Cells

A solar cell is composed of a PIN diode in which light is used to create charge carriers. It may be integrated with a battery of the invention to use the generated electrical energy to charge the battery.

What is claimed is:

1. A solid-state battery, comprising:
a plurality of stacked thin film layers,
wherein the solid-state battery is at least partially integrated within the stacked layers and has a thickness less than about 1 μm.

2. The solid-state battery of claim 1 wherein the stacked thin film layers comprise a cathode layer, an electrolyte layer, and an anode layer.

3. The solid-state battery of claim 2 wherein (i) the electrolyte layer is disposed proximate the cathode layer, the electrolyte layer having a first surface contacting the cathode layer; and (ii) the anode layer is disposed proximate the electrolyte layer, the anode layer contacting a second surface of the electrolyte layer.

4. The solid-state battery of claim 2 wherein the electrolyte comprises silicon dioxide.

5. The solid-state battery of claim 4 wherein the electrolyte is substantially free of lithium.

6. The solid-state battery of claim 4 wherein the electrolyte layer has a thickness less than about 100 nm.

7. The solid-state battery of claim 2 wherein at least one of the anode and cathode comprises silicon.

8. The solid-state battery of claim 2 wherein at least one of the anode and the cathode comprises lithium.

9. The solid state battery of claim 8 wherein at least one of the anode and the cathode comprises at least one of a lithium-metal alloy, a III-V compound, a II-VI compound, a nitride, lithium intercalated into graphite, and an oxide.

10. The solid-state battery of claim 9 wherein at least one of the anode and the cathode comprises at least one of Li₂₂Sn₅, LiCoO₂, titanium nitride, nickel silicide, cobalt silicide, titanium oxide, and a transition metal oxide.

11. The solid-state battery of claim 2 wherein the cathode layer has a thickness less than about 500 nm.

12. The solid-state battery of claim 2 wherein the anode layer has a thickness less than about 500 nm.

13. The solid-state battery of claim 1 wherein the stacked layers are formed on a substrate, and at least a portion of the substrate comprises at least a portion of the solid-state battery.

14. The solid-state battery of claim 13 wherein the substrate comprises an anode.

15. The solid-state battery of claim 13 wherein the substrate comprises a cathode.

16. The solid-state battery of claim 1 wherein the battery is integrated within and operatively connected to an integrated circuit defined on the substrate.

17. The solid-state battery of claim 1, further comprising:
a contact layer disposed over the battery.

18. A method for forming a solid-state battery, comprising the steps of:
forming a plurality of thin film layers over a substrate; and
patterning the plurality of thin film layers to define the solid-state battery,
wherein the solid-state battery has a thickness less than approximately 1 μm.

19. The method of claim 18 wherein the plurality of thin film layers includes a cathode layer, an electrolyte layer, and an anode layer.

20. The method of claim 19 wherein the electrolyte layer comprises silicon dioxide.

21. The method of claim 20 wherein forming the electrolyte layer comprises at least one of dry oxidation and wet oxidation.

22. The method of claim 20 wherein the electrolyte layer has a thickness less than approximately 500 nm.

23. The method of claim 18 wherein forming the layers comprises sputtering.

24. The method of claim 18 wherein forming the layers comprises chemical vapor deposition.

25. The method of claim 18 wherein patterning the layers comprises photolithography.

26. The method of claim 18 wherein patterning the layers comprises etching.

27. The method of claim 18 wherein the solid-state battery is integrated within and operatively connected to an integrated circuit disposed on the substrate

28. A solid-state battery, comprising:
a plurality of stacked thin film layers,
wherein the solid-state battery is at least partially integrated within the stacked thin film layers, the stacked thin film layers comprise an electrolyte layer and the electrolyte layer has a thickness of less than about 100 nm.

29. The solid-state battery of claim 28 wherein the stacked thin film layers further comprise a cathode layer and an anode layer.

30. The solid-state battery of claim 29 wherein (i) the electrolyte layer is disposed proximate the cathode layer, the electrolyte layer having a first surface contacting the cathode layer; and (ii) the anode layer is disposed proximate the electrolyte layer, the anode layer contacting a second surface of the electrolyte layer.

31. The solid-state battery of claim 29 wherein the electrolyte comprises silicon dioxide.

32. The solid-state battery of claim 29 wherein the electrolyte is substantially free of lithium.

33. The solid-state battery of claim 31 wherein the electrolyte layer has a thickness less than about 10 nm.

34. The solid-state battery of claim 29 wherein at least one of the anode and cathode comprises silicon.

35. The solid-state battery of claim 29 wherein at least one of the anode and the cathode comprises lithium.

36. The solid state battery of claim 35 wherein at least one of the anode and the cathode comprises at least one of a lithium-metal alloy, a III-V compound, a II-VI compound, a nitride, lithium intercalated into graphite, and an oxide.

37. The solid-state battery of claim 36 wherein at least one of the anode and the cathode comprises at least one of Li₂₂Sn₅, LiCoO₂, titanium nitride, nickel silicide, cobalt silicide, titanium oxide, and a transition metal oxide.

38. The solid-state battery of claim 29 wherein the cathode layer has a thickness less than about 500 nm.

39. The solid-state battery of claim 29 wherein the anode layer has a thickness less than about 500 nm.

40. The solid-state battery of claim 28 wherein the stacked layers are formed on a substrate, and at least a portion of the substrate comprises at least a portion of the solid-state battery.

41. The solid-state battery of claim 40 wherein the substrate comprises an anode.

42. The solid-state battery of claim 40 wherein the substrate comprises a cathode.

43. The solid-state battery of claim 28 wherein the battery is integrated within and operatively connected to an integrated circuit defined on the substrate.

44. The solid-state battery of claim 28 further comprising:
a contact layer.

45. A method for forming a solid state battery, comprising the steps of:
forming a plurality of thin film layers over a substrate, and
chemical mechanical polishing at least one of the thin film layers.

46. A method for forming a solid-state battery, comprising the steps of:
forming a plurality of thin film layers over a substrate; and
patterning the plurality of thin film layers to define the solid-state battery, the solid-state battery including an electrolyte layer,
wherein the electrolyte layer has a thickness of less than about 100 nm.

47. The method of claim 46 wherein the plurality of thin film layers includes a cathode layer and an anode layer.

48. The method of claim 46 wherein the electrolyte layer comprises silicon dioxide.

49. The method of claim 48 wherein forming the electrolyte layer comprises at least one of dry oxidation and wet oxidation.

50. The method of claim 48 wherein the electrolyte layer has a thickness less than approximately 10 nm.

51. The method of claim 46 wherein forming the layers comprises sputtering.

52. The method of claim 46 wherein forming the layers comprises chemical vapor deposition.

53. The method of claim 46 wherein patterning the layers comprises photolithography.

54. The method of claim 46 wherein patterning the layers comprises etching.

55. The method of claim 46 wherein the solid-state battery is integrated within and operatively connected to an integrated circuit disposed on the substrate

56. The method of claim 46 wherein at least one of the thin film layer comprises polysilicon.

57. A solid-state battery, comprising:
a thin solid electrolyte layer,
wherein the electrolyte layer comprises an initial state and an operative state, the electrolyte layer in the initial state is substantially free of ions, and ions conduct through the electrolyte layer in the operative state during operation of the battery.
